(19) United States
(12) Patent Application Publication
(10) Pub. No.: US 2026/0243524 A1
(43) Pub. Date: Aug. 20, 2026

(54) DOUBLE-SIDED NANOWIRE ARRAY FILMS

(71) Applicant: CARNEGIE MELLON UNIVERSITY, Pittsburgh, PA (US)

(72) Inventors: SHENG SHEN, Pittsburgh, PA (US); RUI CHENG, Pittsburgh, PA (US)

(73) Assignee: CARNEGIE MELLON UNIVERSITY, Pittsburgh, PA (US)

(21) Appl. No.: 18/852,214

(22) PCT Filed: May 9, 2023
(86) PCT No.: PCT/US2023/021477

§ 371 Date: Sep. 27, 2024

Related U.S. Application Data
(60) Provisional application No. 63/341,758, filed on May 13, 2022.

(51) Int. Cl. F28F 13/18; B82Y 30/00; B82Y 40/00; F28F 13/00; H10W 40/00; H10W 40/22; H10W 40/25

(52) U.S. Cl. CPC F28F 13/185; B82Y 30/00; B82Y 40/00; F28F 2013/001; H10W 40/037; H10W 40/228; H10W 40/251; H10W 40/255

(57) ABSTRACT

Disclosed herein is a nanostructured composite thermal interface and a method for fabricating the interface. The interface consists of a metal foil having arrays of metal nanowires disposed on either side thereof. An adhesive polymer is interspersed within the nanowires in each array and serves as a binder to adhere the interface to the surfaces of target objects, for example, a CPU and a heat sink.

### RELATED APPLICATIONS

This application claims the benefit of U.S. Provisional Patent Application No. 63/341,758, filed May 13, 2022, the contents of which are incorporated herein in their entirety.

### BACKGROUND

Efficient heat dissipation is crucial for energy saving and safe operation in energy dense devices and systems. Existing data centers consume about 200 terawatt hours (TWh) each year, which will continue to grow with the development of cloud computing and artificial intelligence. Cooling accounts up to 33-40% of data center energy usage and consumes billions of tons of water per year. Heat fluxes of high-power electronics, such as solid-state lasers, wideband gap transistors, and phased array radars, have reached unprecedented ~1 kw/cm² which, without effective thermal management, will lead to rapid device performance and lifetime degradation.

With heterogeneous integration being more and more inevitable and common in electrical devices and systems, thermal interface resistance, which can constitute more than 50% of the total thermal resistance, has become a bottleneck for thermal management. To thermally bridge and mechanically join the interfaces, thermal interface materials (e.g., greases, compounds, pads, tapes, solders, and epoxies) have been used.

However, it remains a significant challenge to develop a high-performance thermal interface material, because it has to be both thermally conductive and soft to concurrently reduce thermal interface resistance and accommodate thermal stress.

Thermal greases, compounds, and epoxies have high compliance, but they suffer from low thermal conductivity. Solders have a high thermal conductivity but struggle with low mechanical compliance and require a high temperature soldering process and are not applicable for jointing large sections, which significantly hinders their applications as universal joints.

Aligned or ordered nanostructures including carbon nanotubes (CNTs), nanowires, graphene, nanosheets and nanofibers are promising for making thermally conductive and mechanically soft thermal interface materials. However, the fabrication of these nanostructures is generally costly and unscalable. In addition, most of these nanostructures are not adhesive or solderable, and mainly rely on pure dry thermal contact with substrates, which largely compromises their performance.

### SUMMARY

Disclosed herein is a novel nanostructured composite thermal interface (NCTI) and a method of fabrication of the NCTI. In one embodiment, the NCTI consists of a free-standing double-sided copper nanowire (CuNW) array integrated with an adhesive polymer to create a double-sided copper nanowire-polymer composite film. The film can be used as an adhesive, high-performance, paper-like thermal and electrical interface material. Copper nanowire arrays are bottom-up grown on the two sides of a thin copper foil and then coated with an adhesive polymer.

When used for jointing two objects, the nanowires penetrate the coated soft polymer layer to make direct contact by a mild pressure to accommodate the object surface morphology, acting as the efficient heat and current channels. Meanwhile, the high conductivity copper foil in the middle performs as a heat/electric regulator, and the adhesive polymer provides strong bonding to join the interfaces.

### BRIEF DESCRIPTION OF THE DRAWINGS

By way of example, a specific exemplary embodiment of the disclosed system and method will now be described, with reference to the accompanying drawings, in which:

FIG. 1 schematically shows the formation of NCTI where the double-sided nanowire array film performs as a conductive and compliant scaffold and the glue tightly bonds the NCTI with mating surfaces and maintain the structural integrity after curing.

FIG. 2 schematically shows NCTI bonded joints with a tri-layer structure and a SEM image of a cross section of an actual interface.

FIG. 3 schematically shows the compliance of the nanowires with the morphology of the surface of the target object to directly contact the target object to form efficient vertical heat flow channels across the interface, and a SEM image showing a top view of the nanowires penetrating through the adhesive polymer layer to directly contact the substrate surfaces.

FIG. 4 schematically illustrates the steps in the fabrication of the NCTI disclosed herein.

FIG. 5 is a SEM image of a double-sided nanowire array without the adhesive polymer layer.

FIG. 6 illustrates the placement of an NCTI between two target objects.

FIG. 7 is a SEM image showing a cross-sectional view of the double-sided nanowire array without the polymer layer.

FIG. 8 is a SEM image showing a cross-sectional view of the double-sided nanostructured composite film with resin embedded.

FIG. 9 illustrates the thermal and mechanical characterizations of NCTI. (A) is a schematic illustration showing the half-sample for frequency-domain thermoreflectance (FDTR) measurements, and the composition of the thermal resistance. (B) are typical FDTR data plots and best least-square fitting to the heat transfer model; the inset shows the multiple test spots. (C) are histograms summarizing R_{NW-resin/Obj} and K_{NW-resin} extracted from the FDTR measurements at different test spots. (D) is a histogram showing the composition of the total thermal resistances in which the CuNW/resin composite layers take the majority (75.3%). (E) is a graph showing the stiffness characterization of isolated CuNW bundle using in-situ cylindrical flat punch indentation monitored under SEM; the inset shows the SEM image of the nanoindentation process. (F) is a graph showing the tensile strength test of two copper parts bonded by NCTI (blue) and pure AB resin (orange), respectively, showing comparable bonding strength; the inset shows the image of the test sample.

FIG. 10A schematically shows the NCTI applied in a computer between CPU and cooler.

FIG. 10B is a graph comparing the working temperature of the CPU of FIG. 10A using the NCTI versus a thermal paste as the thermal interface material.

### DETAILED DESCRIPTION

A scalable, low-cost nanostructured composite thermal interface (NCTI) is disclosed and, in one embodiment, is made by integrating a free-standing double-sided copper nanowire (CuNW) array with an adhesive polymer.

When used for jointing two objects, the nanowires penetrate the coated soft polymer layer to make direct contact with the surfaces of the target objects by a mild pressure and accommodate the target object surface morphology, to enable the NCTI to act as an efficient heat and current channel. Meanwhile, the high conductivity copper foil in the between the nanowire arrays performs as a heat/electric regulator, and the adhesive polymer provides strong bonding to join the interfaces.

Based on the penetrative metal nanowire scaffold, the NCTI demonstrates an ultra-high thermal conductivity over 100 W/m-K, which is two orders of magnitude higher than those of composite epoxies (~1 W/m-K) and one order of magnitude higher than those of solders (~10 W/m-K). The NCTI also has a high electrical conductivity like metals and was empirically found to be about one order of magnitude more conductive than commercial double-sided copper tapes.

In addition to high thermal and electrical conductivity, the NCTI also has a high mechanical compliance. Both the high aspect ratio copper nanowire array and the adhesive polymer are soft so as to accommodate the thermal stress generated due to possible mismatch of thermal expansion coefficients of the joined objects.

The adhesive, high-performance, paper-like interface film can be directly applied to bond two target objects through a mild pressure at room temperature and without limitation on scales, providing an excellent heat dissipation and electric conduction performance.

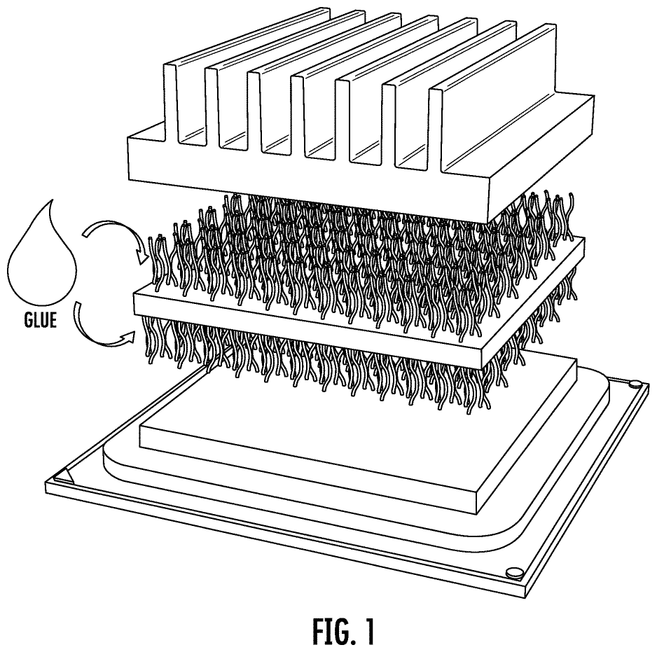

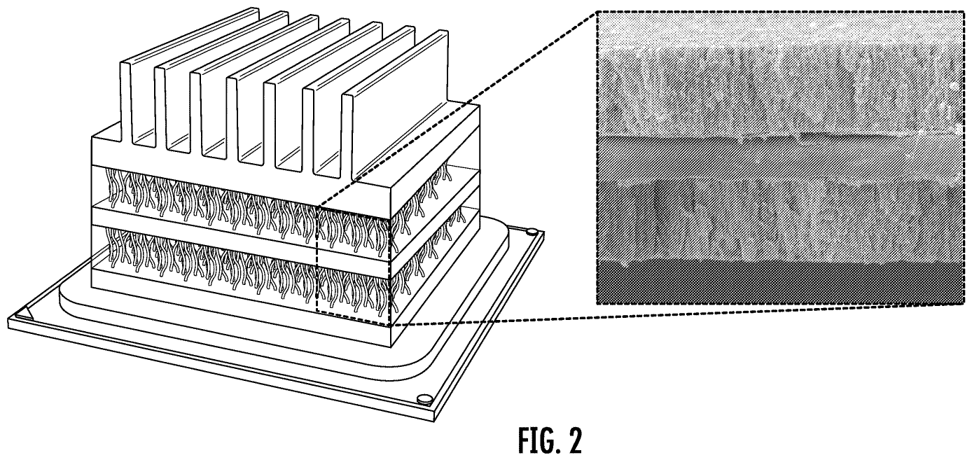

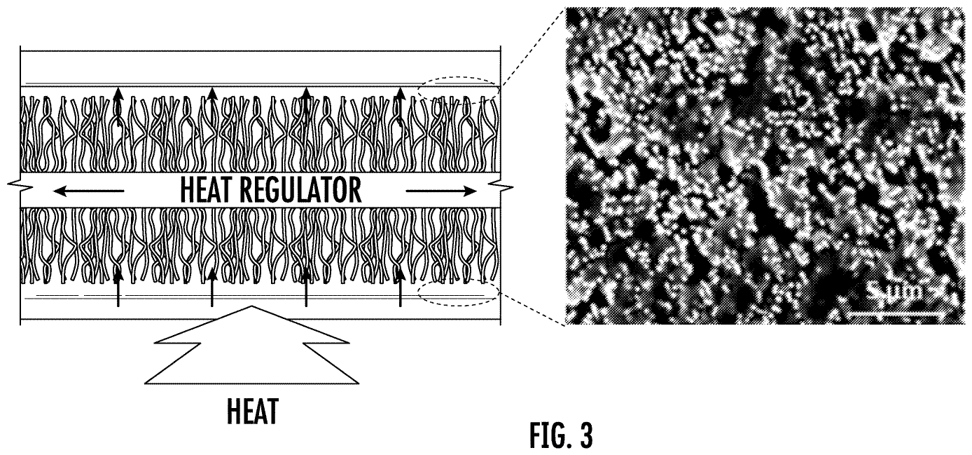

FIG. 1 schematically shows the formation of the NCTI where the double-sided nanowire array performs as a conductive and compliant scaffold and the adhesive polymer tightly bonds the NCTI with mating surfaces of the target objects and maintains the structural integrity after curing. FIG. 2 schematically shows a perspective view of the tri-layer structure of the NCTI bonded joints with a SEM image showing a cross sectional view of an actual interface. FIG. 3 shows a side view of the same interface with a SEM image showing a top view of the NCTI showing the metal nanowires penetrating through the adhesive polymer layer to directly contact the surfaces of the target objects.

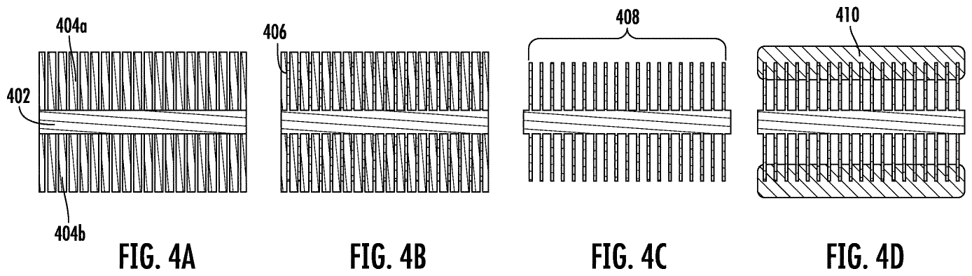

FIG. 4 shows the one possible process for producing the NCTI described herein. In step (a), templates 404a, 404b are attached to opposing sides of a metal foil 402. Templates 404a, 404b are preferably commercially available sheets having holes defined therein through which the nanowires grow. The template may be, in one instance, composed of a polycarbonate material.

In preferred embodiments, metal foil 402 is a copper foil which may be between about 1 μm and 100 μm in thickness and preferably is about 10 μm thick, although in variations other metals may be used. In step (b), the nanowires 406 are deposited, preferably by electrochemical deposition but other methods deposition may also be used. The deposition results in vertically aligned nanowire arrays 408 grown on both sides of metal foil 402. In preferred embodiment, the nanowires are composed of copper, but in variations, other metals may be used.

In some embodiments, the nanowires may be grown by submersing the foil in an electrolyte bath, wherein the electrolyte comprises, for example, copper sulphate. Other electrolytes may be used when growing nanowires composed of a material different from copper. In situations wherein the surfaces of the target objects are irregular or curved, a conformal NCTI may be produced in accordance with a method disclosed in co-pending patent application PCT/US2023/021452, entitled “Growth of Vertically-Aligned Nanowires on Conductive Surfaces”, the contents of which are incorporated herein in their entirety.

In various embodiments, the diameter of the nanowires varies from 10 nm to 30 μm but is preferable in the 50-1000 nm range. In various embodiments, the height of the nanowires varies between approximately 5 μm and 100 μm but is preferably in the 20 μm to 50 μm range. In various embodiments, the nanowires cover between 5% and 50% of the surface area of the metal foil base. Depending upon the application, other diameters, heights, diameter/height ratios and fill ratios may be used.

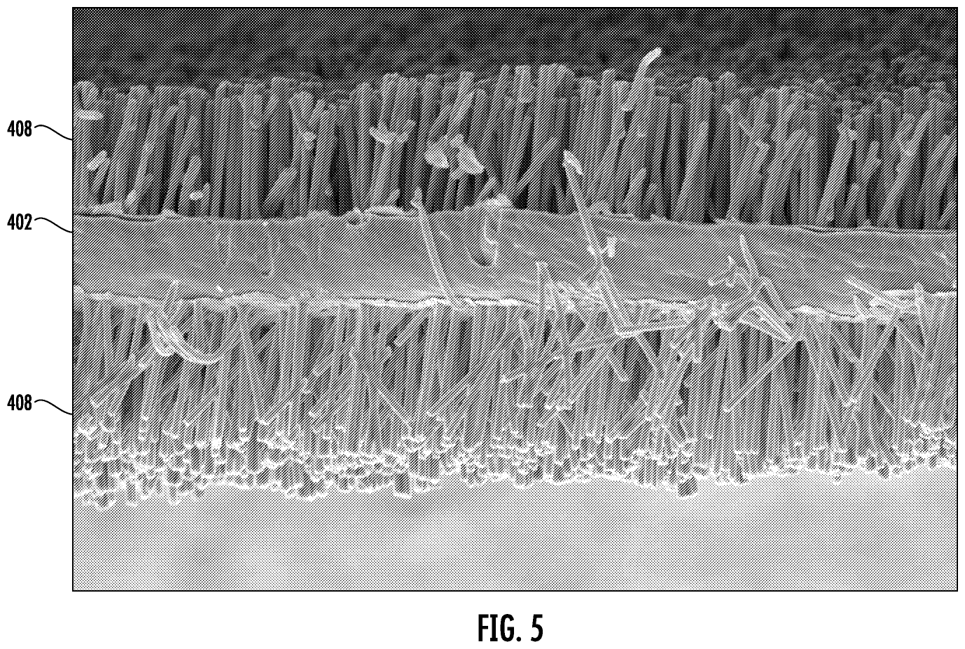

In step (c) of the process, templates 404a, 404b are removed by chemical dissolution. In step (d) of the process, the tops of the nanowire arrays 408 are coated with an adhesive polymer layer 410. FIG. 5 is an image showing the double-sided nanowire array prior to application of the adhesive polymer. Preferably, the adhesive polymer has a viscosity less than or equal to 10,000 cP. In one embodiment, adhesive polymer may be EpoxySet #145-20005, 100:12, mixed with hardener #145-20010, with viscosity of 300 cP, manufactured by Allied High Tech Products Inc. of Cerritos, California. Other equivalent products may be used.

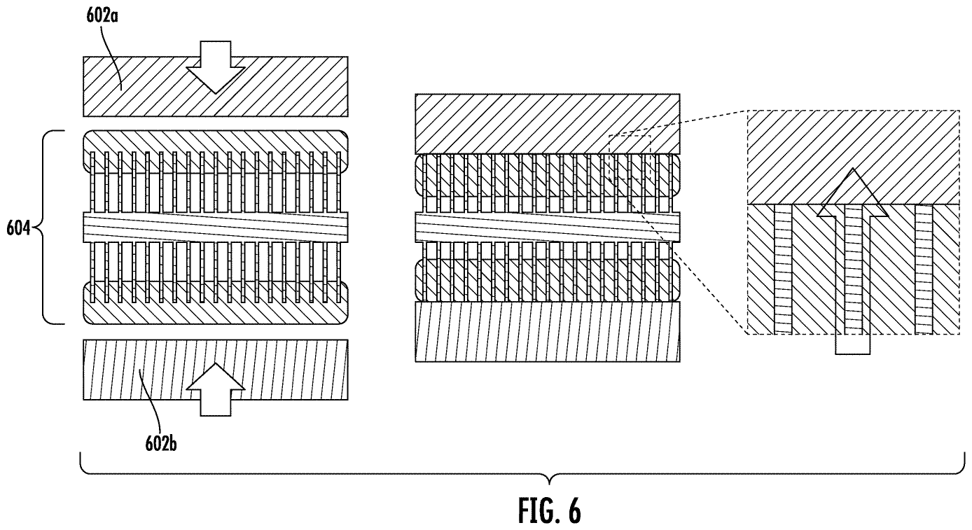

FIG. 6 shows the process of mating the NCTI with target objects 602a, 602b. NCTI 604 is placed between the surfaces of target objects 602a, 602b and a mild pressure is applied. The pressure forces adhesive polymer 410 between nanowires 406 of nanowire arrays 408. The applied pressure causes the nanowires 406 to penetrate through the adhesive polymer layer and contact the surfaces of the target objects 602a, 602b, which significantly contributes to the high thermal and electrical performance of the material. Preferably, the pressure required is less than or equal to 1000 psi.

FIG. 2 shows a second image of an actual NCTI in accordance with this disclosure, showing the adhesive polymer coating the nanowires. This view is similar to the schematic view shown in the inset in FIG. 6. The inset of FIG. 3 shows the tops of the nanowires penetrating the adhesive polymer layer to allow contact with the surface of the target object (not shown).

In some embodiments, the double-sided nanowire arrays 408, in conjunction with the center Cu base layer 402 perform as a conductive and compliant scaffold due to the high thermal conductivity of copper and the high aspect ratio (>100) of nanowires 406. In some embodiments, the adhesive polymer layer may be a low-viscosity glue (e.g., resin, epoxy, super glue, etc.), the application of which will cause a strong capillary force arising from the high surface energy of nanowire arrays 408 with the adhesive polymer 410 to allow for tight bonding of the nanostructured scaffold with mating surfaces of the target objects, as previously described. It should be noted that one advantage of the NCTI is that it allows for room temperature bonding, compared with the soldering process, which occurs at a much higher temperature (typically >200° C.). This allows for broader applications for various environments and materials.

In some embodiments, before curing the glue, the compliance of the nanowire arrays is important to ensure that the nanowires comply with the substrate morphology of the surface of the target object and directly contact the surface to form efficient vertical heat flow channels across the interface. In some embodiments, the high thermal conductivity base layer 402 (i.e., a copper foil in the preferred embodiment) between the nanowire arrays 408 acts as a lateral heat regulator for collecting and spreading heat, as shown in FIG. 3, leading to increased heat flux uniformity. In some embodiments, the NCTI may synergistically regulate heat flow along an interface in both out-of-plane and in-plane directions, which is an important advantage as compared with vertically aligned CNTs, nanowires, and nanofibers. In some embodiments, in contrast to pure dry contacts, after the glue curing, the contacts between the nanowires and the mating substrate may be secured and anchored, as will without applying any external pressure, thus providing strong interfacial bonding and resilience to thermal cycles and vibrations.

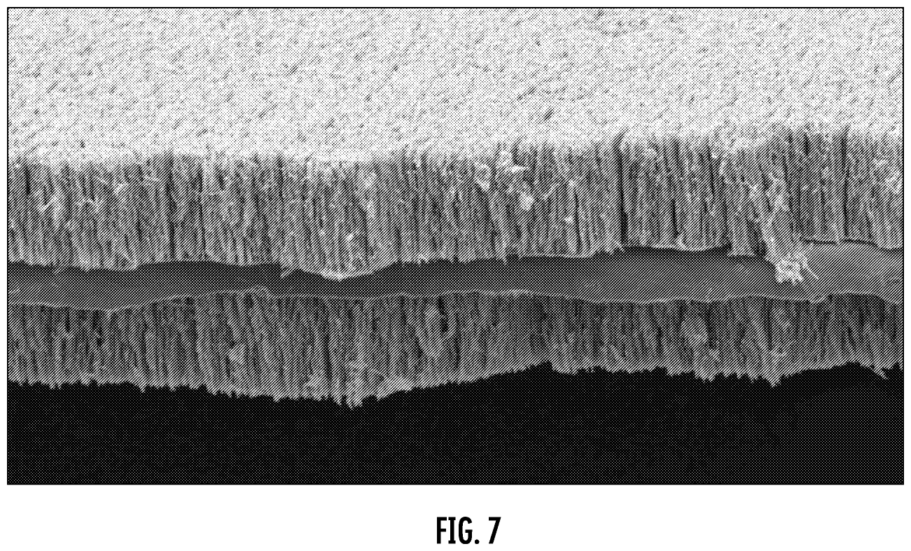

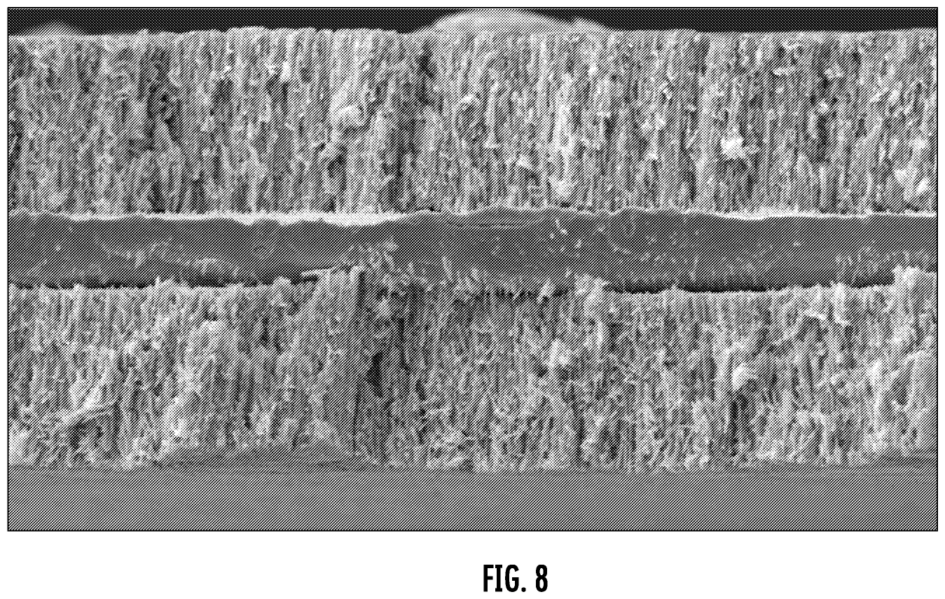

FIG. 7 is a SEM image showing a cross-sectional view of the double-sided nanowire array without the polymer, while FIG. 8 is a SEM image showing a cross sectional view after the polymer has been applied.

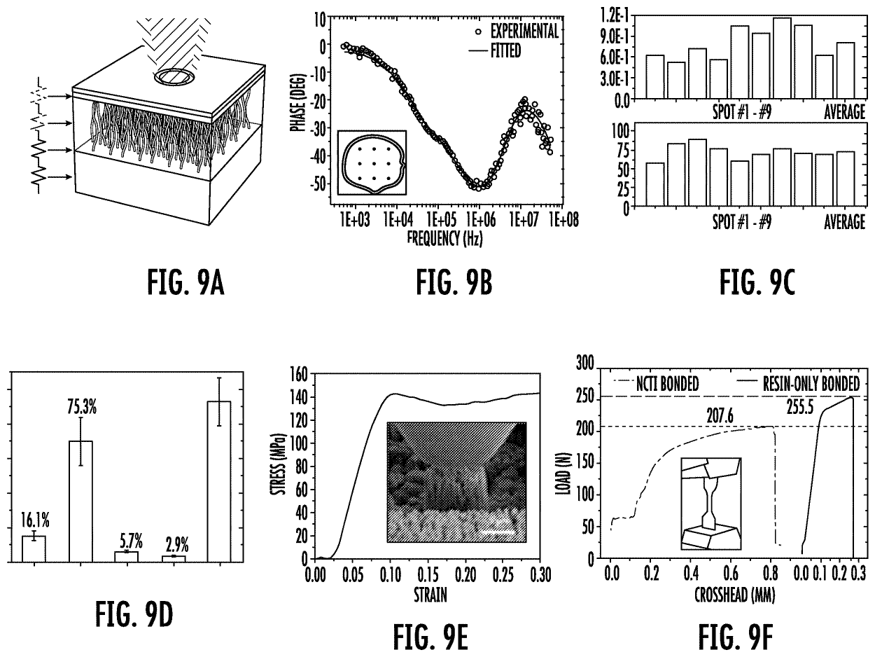

In real applications, it is important to measure both the thermal transport property of the NCTI and the thermal interface resistance between the NCTI and a substrate. Frequency-domain thermoreflectance (FDTR) methods may be used to measure the thermal transport properties of the NCTI. As shown in FIG. 9A, the FDTR method is a pump-probe optical technique in which the modulated pump beam excites the sample while the probe beam measures the changes in the temperature-dependent reflectance. The phase lag between the pump and probe lasers may be measured as a function of the modulation frequency, where the thermal properties including in-plane and cross-plane thermal conductivities and thermal interface resistance of the sample may be extracted by fitting the measured data to a 2D heat conduction model for multilayer thin films. Due to the symmetry of the NCTI, half of the thermal interface may be characterized, as depicted in FIG. 9A, in which the sample may be fabricated using a resin as the adhesive polymer and bond the nanowires with a Cu substrate.

In FIG. 9(B-D), FDTR measurements may be conducted at 9 different locations on the sample from both sides (half of the NCTI). When using resin as the adhesive polymer, the average thermal conductivity of the 25 μm thick CuNW/resin composite can be measured to be 71.6±14.1 W/mK, corresponding to a thermal resistance of 0.349±0.069 mm²·K/W. As a comparison, the measured thermal conductivity of the 10 μm Cu-base layer in the middle of the NCTI can be 376.6±37.7 Wm·K. The thermal interface resistances at CuNW-resin/substrate and CuNW-resin/Cu-base interfaces can be measured to be 0.075±0.013 mm² K/W and 0.027±0.005 mm²·K/W, respectively. Based on these FDTR measurements, the total thermal resistance of the NCTI in a fully bonded sample (including thermal interface resistances) can be estimated to be 0.928 ±0.140mm 2·K/W, by assuming that the NCTI may be symmetrically bonded between two Cu substrates.

As shown in FIG. 9D, CuNW/resin composite layers can give rise to the majority (75.3%) of the total thermal resistance. In FIG. 9E, the Young's modulus of the nanowire array (d=200 nm) is characterized to ~2.5 GPa through the in-situ cylindrical flat punch (d=10 μm) indentation, which is two orders of magnitude lower than that of bulk copper. Such a soft structure thereby allows a strong morphology compliance under mild external pressure during the bonding process. The bonding strength of CuNW-resin can be measured and compared with the pure resin, as shown in FIG. 9F. The maximum tolerance load of CuNW-resin can be measured to be 207.6 N, which exhibits a comparably strong bonding strength with the pure resin (255.5 N) for a bonding area of 5×14mm².

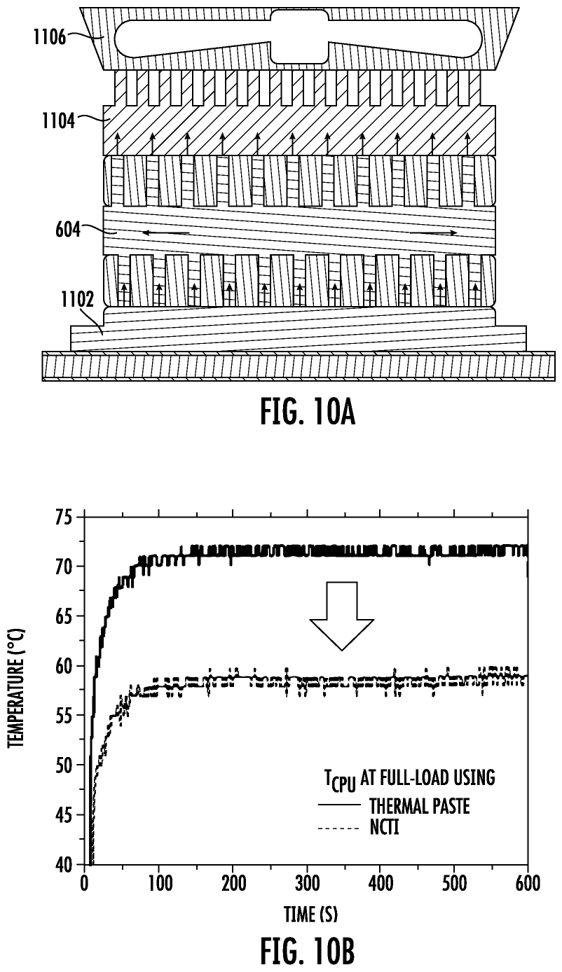

The NCTI was also tested on a CPU for a realistic cooling test, as shown schematically in FIG. 10A, showing the NCTI 604 disposed between a CPU 1102 and a heat sink 1104 equipped with a cooling fan 1106. An open desktop equipped with a 65 W standard office level CPU 1102 and an air cooler were assembled as the test platform. The cooling performance of the NCTI is shown graphically in FIG. 10B. The performance of the NCTI was evaluated by monitoring the temperature of CPU 1102 at full load using its built-in temperature sensors and benchmarking it with a commercial thermal paste at the same thickness of 60 μm. As can be seen in the graph in FIG. 10B, the thermal paste allows for a stable full-load operation of CPU 1102 at the measured temperature of ~72° C. and energy consumption of approximately 70.8 W. In contrast, with the NCTI, the working temperature of CPU 1102 is significantly decreased to ~58° C., demonstrating the superior thermal performance of this new material.

Noteworthily, the CPU energy consumption decreases to only about 66.6 W with a considerably saved amount of about approximately 4.2 W (about 5.9%). In some embodiments, based on a simple and low-barrier replacement using the NCTI, more powerful CPUs may be assembled on the existing smart devices with a significant performance improvement without increasing the working temperature. Thus, the NCTI offers a low-cost upgrade solution beyond hardware upgrades for all classes of electronic devices and systems including, but not limited to, data centers and portable devices. On the other hand, even if all hardware remains original, the NCTI may benefit electronic devices or systems by allowing them to operate at much lower temperature and saving energy by reducing the production of waste heat. This will have implications on a wide range of semiconductor devices and save considerable amount of energy.

As would be realized by one of skill in the art, many variations on implementations discussed herein which fall within the scope of the invention are possible. For example, the method may use different materials for the metal foil base and the nanowires. Various embodiments may have nanowires with differing heights, diameters, height-to-diameter ratios and fill ratios. The density of the nanowires may differ, depending on the template used. The length of time for growing the nanowires may also vary, depending on the application. Lastly, various embodiments may use differing materials as the adhesive polymer. Many variations on both the fabricated NCTI array and the fabrication process are possible and are contemplated to be within the scope of the invention.

Moreover, it is to be understood that the features of the various embodiments described herein are not mutually exclusive and can exist in various combinations and permutations, even if such combinations or permutations were not made express herein, without departing from the spirit and scope of the invention. Accordingly, the exemplary device and method disclosed herein is not to be taken as a limitation on the invention but as an illustration thereof. The scope of the invention is defined by the claims which follow.

1. A nanostructured interface comprising:
a conductive film or foils; and
arrays of conductive nanowires disposed on both sides of the conductive film or foil.

2. The nanostructured interface of claim 1 further comprising:
an adhesive polymer interspersed within the nanowires in each array, forming a composite film.

3. The nanostructured interface of claim 1 wherein the nanowires contact with an object surface by squeezing out extra adhesive polymer.

4. The nanostructured interface of claim 1 wherein the metal foil and the nanowires are composed of copper.

5. The nanostructured interface of claim 1 wherein the nanowires are between 10 nm and 30000 nm in diameter.

6. The nanostructured interface of claim 1 wherein the nanowires are between 5 μm and 100 μm in height.

7. The nanostructured interface of claim 1 wherein the nanowires cover between 5% and 50% of each side of the metal foil.

8. The nanostructured interface of claim 1 wherein the metal foil is between 1 μm and 100 μm in thickness.

9. The nanostructured interface of claim 2 wherein the adhesive polymer is a low-viscosity resin or glue or epoxy.

10. The nanostructured interface of claim 2 wherein the composite film bonds to surfaces of target objects after the adhesive polymer is cured.

11. A method comprising:
providing a conductive foil;
attaching templates to opposing sides of the metal foil, the templates each defining a plurality of holes therein;
growing thermally conductive nanowires through the holes of the templates to create nanowire arrays on opposing sides of the foil; and
dissolving the templates.

12. The method of claim 11 further comprising:
coating the thermally conductive nanowire arrays with an adhesive polymer to form a composite film.

13. The method of claim 12 further comprising:
placing the composite film between surface of two target objects;
applying a pressure to force the adhesive polymer to fill spaces between the nanowires of each nanowire array; and
curing the adhesive polymer to bind the composite film to the surfaces of the target objects.

14. The method of claim 13 wherein the applied pressure causes tips of the metal nanowires to contact the surfaces of the target objects.

15. The method of claim 11 wherein the metal foil and the nanowires are composed of copper.

16. The method of claim 12 wherein the adhesive polymer is a low-viscosity resin or glue or epoxy.

17. The method of claim 11 wherein the nanowires are between 10 nm and 30000 nm in diameter.

18. The method of claim 11 wherein the nanowires are between 5 μm and 100 μm in height.

19. The method of claim 11 wherein the nanowires cover between 5% and 50% of each side of the conductive foil.

20. The method of claim 11 wherein the conductive foil is between 1 μm and 100 μm in thickness.

21. The method of claim 12 wherein the adhesive polymer has a viscosity of less than or equal to 10,000 cP.

22. The method of claim 13 wherein the applied pressure is less than or equal to 1000 psi.
